(19) United States
(12) Patent Application Publication
(10) Pub. No.: US 2010/0310860 A1
(43) Pub. Date: Dec. 9, 2010

(54) SYNTHETIC METHOD FOR ANTI-OXIDATION CERAMIC COATINGS ON GRAPHITE SUBSTRATES

(75) Inventors: Yeon Gil Jung, Changwon-si (KR); Sang Won Myoung, Masan-si (KR); Ji Hun Kang, Hadong-gun (KR); Jeong-Pyo Kim, Dongnae-gu (KR)

Correspondence Address: SCHMEISER, OLSEN & WATTS, 22 CENTURY HILL DRIVE, SUITE 302, LATHAM, NY, 12110, US

(73) Assignee: Changwon National University Industry Academy Cooperation Corps

(21) Appl. No.: 12/745,276

(22) PCT Filed: Feb. 28, 2008
(86) PCT No.: PCT/KR08/01158

§ 371 Date: May 28, 2010

(51) Int. Cl. B32B 9/00; C23C 16/32; C23C 16/34

(52) U.S. Cl. 428/332; 427/249.16; 427/255.394

(57) ABSTRACT

A method of forming an SiC or SiC/Si₃N₄ coating layer on a bare graphite substrate via a solid-vapor process is disclosed. Synthesis of the SiC coating layer on the graphite substrate is accomplished by reaction of SiO vapor and carbon (C) of the graphite, and that of the SiC/Si₃N₄ coating layer is accomplished by reaction of SiO vapor, N₂ and C of the graphite. Thickness of the SiC coating layer is affected by porosity of the graphite substrate, reaction temperature, and dwell time. By controlling the reaction temperature, hardness of the SiC coating may be increased to 10-15 times that of the bare graphite substrate. The SiC/Si₃N₄ coating is much thinner than the SiC coating and has a higher surface hardness. Thermal oxidation tests show that the SiC or SiC/Si₃N₄ coated substrate exhibits improved oxidation resistance over bare substrates. In particular, the SiC/Si₃N₄ coated substrate shows outstanding resistance to thermal oxidation.

### TECHNICAL FIELD

The present invention relates to a carbon material, and more particularly to a carbon material useful for engineering components of electrical contacts, heat exchangers, rockets, aircraft, and the like.

### BACKGROUND ART

Carbon materials are attractive materials for high temperature applications due to their high strength, high modulus, excellent thermal shock resistance, and light weight. They are widely used as engineering materials, such as heaters, electrical contacts, high-temperature heat exchangers, rocket nozzles and leading edges of aircraft wings, etc. Among various carbon materials, graphite is the most widely used.

However, the use of graphite materials has been greatly restricted due to their poor resistance to oxidation at high temperature in an oxidizing atmosphere. Achieving good oxidation resistance is essential to utilization of their full potential as high-temperature materials.

Prevention of oxidation of graphite materials has been extensively studied in the past 60 years. Ceramic coatings are commonly employed to protect graphite materials from oxidation. Although several coating systems have been developed, silicon carbide (SiC) is considered as the best coating material due to its good mechanical properties, low density, good physical-chemical compatibility with graphite, and excellent oxidation resistance at high temperature. Also, silicon nitride (Si₃N₄) coating is of great scientific and technological interest because of good wear resistance, high hardness, chemical inertness, and excellent oxidation resistance at high temperature thereof. These properties allow SiC and Si₃N₄ coatings to meet the conditions required for a variety of applications, and the SiC and Si₃N₄ coatings are considered to be the most efficient method to overcome the shortcoming of the graphite materials.

In general, the SiC coating is formed by the reaction-formed process. In the reaction-formed process, molten silicon reacts with carbon atoms of the graphite substrate to form an SiC coating. Additional processes such as chemical vapor deposition (CVD) and chemical vapor reaction (CVR) are also used to form a ceramic coating on the graphite substrate.

A solid-vapor reaction (SVR) process for forming a ceramic coating layer on the carbon material is a modified CVD process, whereby the surface of the substrate is activated to form a heat-resistant ceramic coating. The SVR process is advantageous over other processes in that a uniform coating can be obtained at low cost. However, this technique provides only a limited coating thickness, owing to the diffusion barrier, and makes only a single phase ceramic layer.

As such, the ceramic coating formed by the conventional SVR process contributes little to the improvement of the mechanical properties of the substrate. Especially, there is little systematic work related to the mechanical properties, such as hardness and wear resistance, thereabout.

### DISCLOSURE

### Technical Problem

Therefore, the present invention has been made in view of the above problems, and it is an object of the present invention to provide a method of modifying a graphite substrate by forming a ceramic coating layer having superior resistance to thermal oxidation and superior mechanical properties on the graphite substrate. Particularly, the present invention provides a method of modifying the graphite substrate by forming SiC and/or SiC/Si₃N₄ coating layers with sufficient thickness, in order to improve hardness and wear resistance of the coating layers.

### Technical Solution

In accordance with an aspect of the present invention, the above and other objects can be accomplished by the provision of a method of modifying a graphite substrate by forming an SiC coating layer on the surface of the graphite substrate. Silicon (Si) powder and silicon dioxide (SiO₂) powder are added to a high-temperature reaction chamber holding a bare graphite substrate. Then, while supplying an inert gas and hydrogen, the high-temperature reaction chamber is heated at a temperature of 1400˜4600° C. for 3 to 9 hours to form a 50 μm to 1000 μm thick SiC coating layer on the surface of the graphite substrate.

In accordance with another aspect of the present invention, a method of modifying a graphite substrate by forming an SiC/Si₃N₄ coating layer on the surface of a graphite substrate is provided. Si and SiO₂ powders are added to a high-temperature reaction chamber holding a bare graphite substrate. Then, while supplying N₂ gas, the high-temperature reaction chamber is heated at a temperature of 1450˜1650° C. for 3 to 9 hours to form a 30 μm to 600 μm thick SiC/Si₃N₄ coating layer on the surface of the graphite substrate.

The bare graphite substrate may have a porosity in the range of 5˜20%.

In accordance with a further aspect of the present invention, a graphite substrate modified by the aforementioned modification methods is provided.

### ADVANTAGEOUS EFFECTS

Through an SVR process with optimized reaction conditions, SiC and SiC/Si₃N₄ coating layers having superior mechanical properties are formed on the graphite substrate. The inventors have succeeded in forming a multi-phase coating layer by optimizing porosity of graphite, reaction temperature and dwell time. Consequently, mechanical properties such as hardness and wear resistance, and resistance to thermal oxidation were significantly improved. Specifically, hardness of the SiC coating layer increased to 10˜15 times that of the graphite substrate. The SiC/Si₃N₄ coating layer exhibited higher hardness than the SiC coating layer, although it was thinner. Resistance to thermal oxidation was significantly improved, as evidenced by the following. Weight loss of the graphite coated according to the present invention at high temperature decreased significantly as compared to bare graphite. Particularly, the SiC/Si₃N₄ coating exhibited superior resistance to thermal oxidation.

### DESCRIPTION OF DRAWINGS

FIG. 1 is a graph depicting changes of free energy for possible chemical reactions related to the formation of coating layers, depending on reaction temperature;

FIG. 2 shows XRD patterns of SiC coatings formed on graphite substrates with different porosities of (A) 10% and (B) 13% for dwell time of 6 hours under Ar/H₂ atmosphere at different temperatures of (a) 1400° C., (b) 1450° C., and (c) 1500° C.;

FIG. 3 shows XRD patterns of SiC coatings at different dwell times;

FIG. 4 shows XRD patterns of SiC/Si₃N₄ coatings at different dwell times;

FIG. 5 shows cross-sectional electron micrographs of SiC coatings at different reaction temperatures;

FIG. 6 shows cross-sectional electron micrographs of SiC/Si₃N₄ coatings at different dwell times;

FIG. 7 is graphs depicting hardness values of SiC coatings formed on graphite substrates with different porosities of (A) 10% and (B) 13% at different reaction temperatures;

FIG. 8 is graphs depicting hardness values of SiC coatings formed on graphite substrates with different porosities of (A) 10% and (B) 13% with different dwell times;

FIG. 9 is graphs depicting hardness values of SiC/Si₃N₄ coatings formed on a graphite substrate with a porosity of 10% with different dwell times;

FIG. 10 is graphs for comparing acoustic emission counts during scratch tests on SiC coatings formed on graphite substrates and on bare graphite substrates;

FIG. 11 is graphs for comparing the results of heat treatment tests performed on bare graphite substrates, SiC coated graphite substrates, and SiC/Si₃N₄ coated graphite substrates at 800° C.;

FIG. 12 is surface micrographs of bare graphite substrates before and after oxidation tests at 800° C. for 150 minutes;

FIG. 13 is surface and cross-sectional micrographs of SiC coated graphite substrates (A-1 and B-1) before oxidation tests, (A-2 and B-2) after oxidation tests at 800° C. for 150 minutes, and (A-3 and B-3) after oxidation tests at 1100° C. for 150 minutes; and

FIG. 14 is surface and cross-sectional micrographs of SiC/Si₃N₄ coated graphite substrates (A-1 and B-1) before oxidation tests, (A-2 and B-2) after oxidation tests at 800° C. for 150 minutes, and (A-3 and B-3) after oxidation tests at 1100° C. for 150 minutes.

### BEST MODE

According to the present invention, SiC and Si₃N₄ coatings are formed on a graphite substrate by a SVR process, in which carbon atoms of the graphite substrate are reacted directly. Microstructure, elemental distribution, hardness, and wear resistance of the synthesized coating layers depending on reaction conditions were investigated. Specifically, effects of graphite porosity, reaction gas, reaction temperature, and dwell time on microstructural evolution and mechanical properties were investigated.

### Mode for Invention

### Synthesis of SiC and SiC/Si₃N₄ Coating Layers on Graphite Substrates

Two kinds of graphite substrates with different porosities of 10% and 13% were cut from 2D-graphite. Graphite specimens with a size of 10×10×10 mm were used as the substrates.

Before coating, the substrates were polished using a 3 μm diamond paste, and then ultrasonically washed (Sonifier 450, Branson, VWR Scientific Co., USA) in isopropyl alcohol for 10 minutes. Silicon (Si, Daejung Chemicals & Metals Co., Ltd., Korea) and silicon dioxide (SiO₂, Junsei, Tokyo, Japan) powders for generating SiO vapor were mixed in a molar ratio of 1:1.

The mixed powders and the substrates were kept in an alumina crucible and then heated to generate vapor at different temperatures with different dwell times at a heating rate of 5° C./min in an Ar/H₂ (160:40) flow of 200 ml/min for SiC coating and N₂ flow of 200 ml/min for SiC/Si₃N₄ coating.

Structural analysis of the synthesized materials was carried out by an X-ray diffraction (XRD, Philips X-pret MPD, Model PW3040, Eindhoven, the Netherlands) employing Cu—Kα radiation. Microstructure of the synthesized materials was observed by a scanning electron microscopy (SEM, JEOL Model JMS-840, Tokyo, Japan) and line spectrums were analyzed using an energy dispersive X-ray spectrometer (EDS, 52700, Hitachi, Japan).

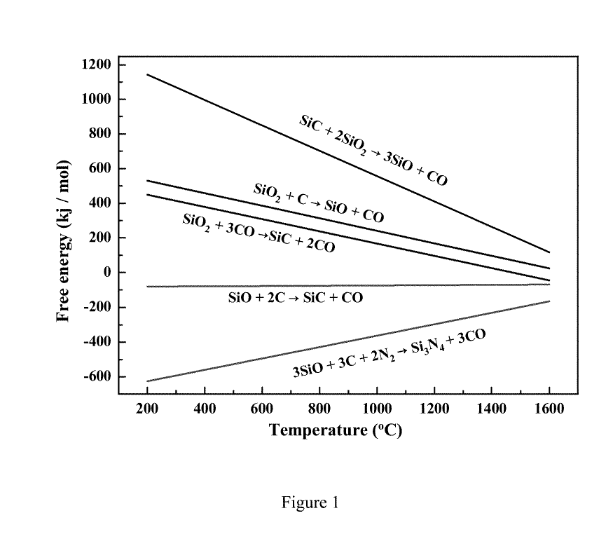

FIG. 1 is a graph depicting changes of free energy for possible chemical reactions related with the formation of coating layers, depending on reaction temperature. Referring to FIG. 1, the free energy for generation of SiO vapor decreases with increasing temperature, whereas the free energy for generation of SiC and Si₃N₄ increases with increasing temperature.

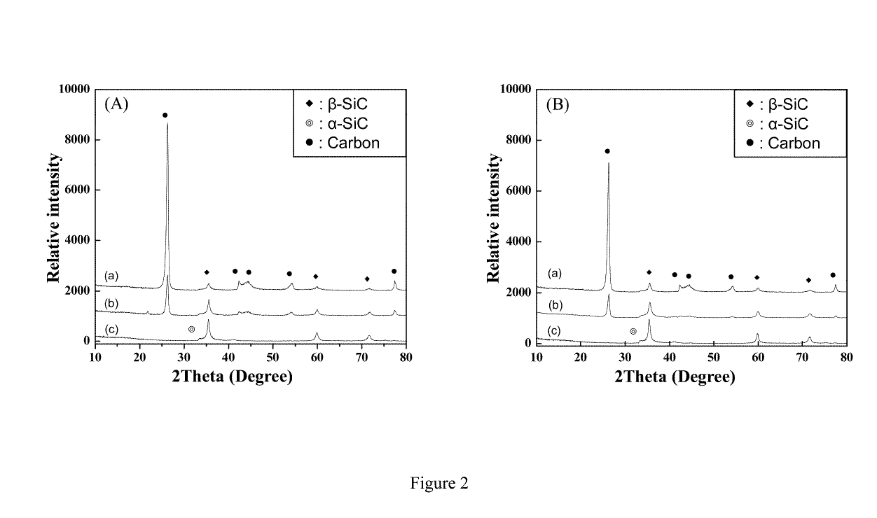

FIG. 2 shows XRD patterns of SiC coatings formed on graphite substrates with different porosities of (A) 10% and (B) 13% for dwell time of 6 hours under Ar/H₂ atmosphere at different temperatures of (a) 1400° C., (b) 1450° C., and (c) 1500° C.

Referring to FIG. 2, the coating layers mainly consist of SiC phases and carbon residues at relatively low temperatures of 1400° C. and 1450° C. However, with the increase of reaction temperature, more SiC layers were formed and all carbon residues were converted to SiC phases when the temperature reached 1500° C.

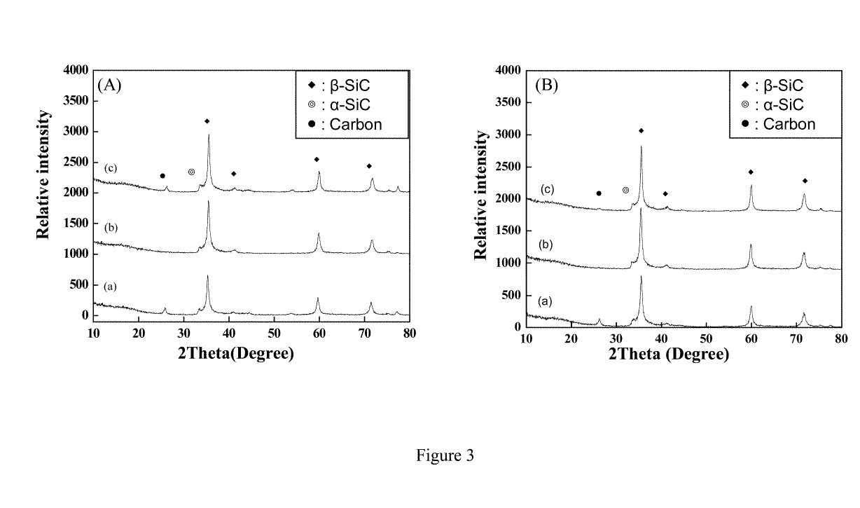

FIG. 3 shows XRD patterns of SiC coatings at different dwell times. The formation of the coatings was performed on graphite substrates with different porosities of (A) 10% and (B) 13% for dwell times of (a) 3 hours, (b) 6 hours, and (c) 9 hours under Ar/H₂ atmosphere at 1500° C.

Referring to FIG. 3, the synthesized coating layers consist of mainly β-SiC of FCC structure with a very small amount of pseudo α-SiC. A small amount of carbon residues were present when dwell time was 3 hours, but, with the dwell time increasing to 6 hours, there remained no carbon residues. This is caused by the fact that the diffusion rate of Si into graphite is slow, and a long dwell time is thus needed to obtain a thick and pure SiC coating. However, in the case of a longer dwell time of 9 hours, carbon peaks appeared again in both XRD patterns, owing to decomposition of the synthesized SiC.

Accordingly, in order to synthesize a pure SiC coating layer with as few carbon residues as possible, optimization of the reaction conditions including reaction temperature and dwell time, independent of the porosity of graphite, is necessary. It is assumed that an insignificant difference found in either XRD pattern was caused by a very small degree of crystallization.

However, it is easier to synthesize an SiC coating layer on the graphite with a porosity of 13% than 10%, because the increase of cumulative contact area is larger at 13% porosity.

The SiC coating is synthesized via SVR as follows:

Si(solid)+SiO₂(solid)→2SiO(vapor) (1)

SiO(vapor)+2C(from graphite)→SiC(solid)+CO(vapor) (2)

First, the SiO vapor is generated from the powder mixture of Si and SiO₂ and reacts with carbon (C) to form SiC on the surface of the graphite, and then diffusion occurs, growing the SiC layer into the graphite.

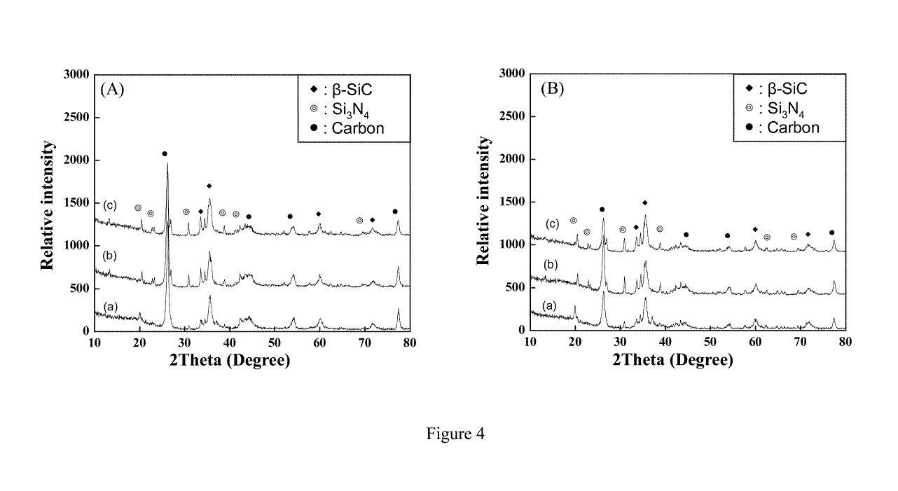

In FIG. 4, XRD patterns of SiC/Si₃N₄ coatings synthesized on graphite substrates with different porosities of (A) 10% and (B) 13% and different dwell times of (a) 3 hours, (b) 6 hours and (c) 9 hours at 1550° C. under N₂ atmosphere are shown.

Referring to FIG. 4, more SiC and Si₃N₄ were formed on the graphite with a porosity of 13% than of 10%. The results indicate that more SiC and Si₃N₄ coating layers are synthesized on the graphite with a porosity of 13% because it passes a larger amount of SiO vapors to react with carbon in the graphite. The formation of the SiC phase is similar to that in the Ar/H₂ atmosphere. N₂ participates in the synthesis of the Si₃N₄ coating layer, as follows:

3SiO(vapor)+2N₂(vapor)+3C(from graphite)→Si₃N₄(solid)+3CO(vapor) (3)

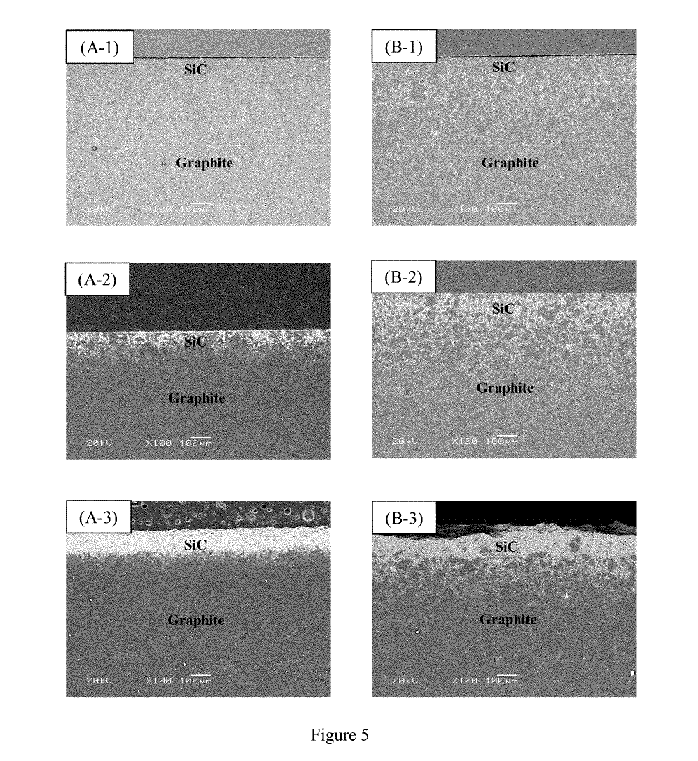

FIG. 5 shows cross-sectional micrographs of SiC coatings at different reaction temperatures. The coatings were formed on graphite substrates with different porosities of (A) 10% and (B) 13% under Ar/H₂ atmosphere with a dwell time of 6 hours, at (A-1 and B-1) 1400° C., (A-2 and B-2) 1450° C., and (A-3 and B-3) 1500° C.

In FIG. 5, the SiC coating layer is shown in white, and the graphite is shown in gray. Comparing (A-1) to (A-3), and (B-1) to (B-3), the SiC layer became thicker and denser as the synthesis temperature increased. The thickness of the SiC coating layer on the graphite with a porosity of 13% is thicker than on the graphite with a porosity of 10%. Also, some SiC phases were grown into the graphite along the pores, which is mainly caused by SiO vapors diffusing into the inside surface of the graphite pores.

The synthesized SiC coating layer adheres well to the graphite substrate and no cracks are formed therebetween. However, the thickness is not much affected by the dwell time. Therefore, it can be confirmed that the thickness of the coating layer is mainly affected by the porosity and the synthesis temperature. The thicknesses of coatings are about 200 μm and 400 μm for substrates with porosities of 10% and 13%, respectively.

From EDS analysis, it was found that the SiC layer on the graphite with a porosity of 13% provides a gradual change in Si distribution. This indicates that the diffusion rate of Si into the graphite is not sufficiently high. As a result, the pores inside the graphite mainly affect formation of SiC in the graphite substrate.

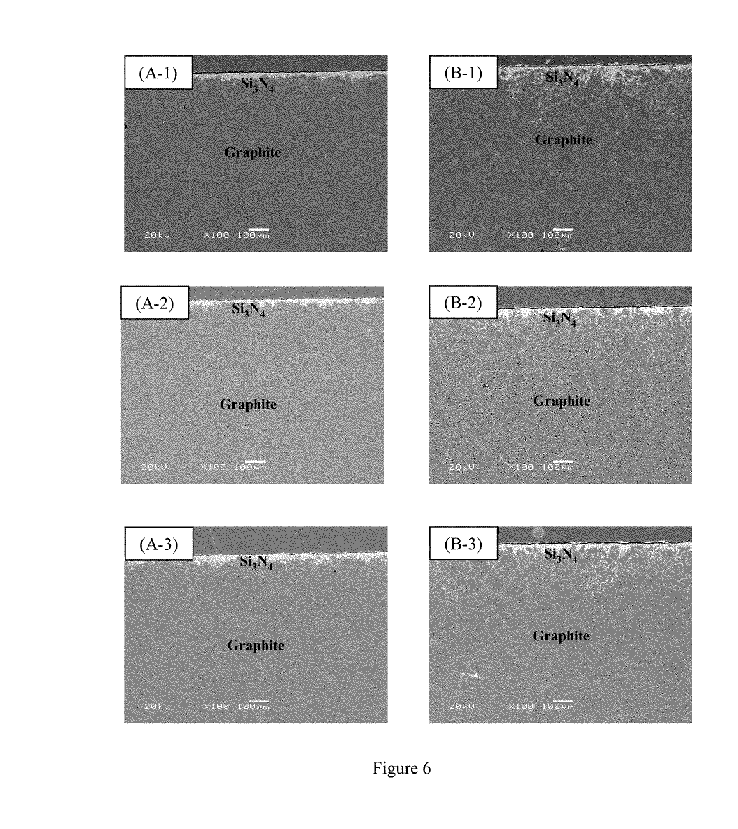

FIG. 6 shows cross-sectional micrographs of SiC/Si₃N₄ coatings at different dwell times. The coatings were formed on graphite substrates with different porosities of (A) 10% and (B) 13% under N₂ atmosphere at 1500° C. with dwell times of (A-1 and B-1) 3 hours, (A-2 and B-2) 6 hours and (A-3 and B-3) 9 hours.

In the micrographs of FIG. 6, the SiC/Si₃N₄ coating layer is shown in white, and the graphite is shown in gray. Referring to (A-3) and (B-3) of FIG. 6, the thickness of the SiC/Si₃N₄ coatings is about 50 μm and 100 μm for the substrates with porosities of 10% and 13%, respectively. That is, the SiC/Si₃N₄ coating layers synthesized under N₂ atmosphere are thinner than those synthesized under Ar/H₂ atmosphere. Under N₂ atmosphere, the thickness of the SiC/Si₃N₄ coating layers did not increase significantly even when the reaction temperature was raised to 1600° C. There were some SiC/Si₃N₄ phases along the pores inside the graphite substrate. The dwell time has little effect on the thickness of the coating layers. The dwell time only affected the densification of the coating layers.

Comparing FIG. 5 to FIG. 6, it can be seen that it is easier to form thick SiC coating layers on the graphite under Ar/H₂ atmosphere than to form thick SiC/Si₃N₄ coating layers under N₂ atmosphere. Even when the synthesis temperature is increased to 1550° C., it is difficult to synthesize thick SiC/Si₃N₄ coatings on the graphite. This indicates that N₂ atmosphere restricts the reaction of the SiO vapors and carbon in the graphite substrate, and the growth of the Si₃N₄ coating layers. Thus, the increase of synthesis temperature under N₂ atmosphere seems to enhance not only the growth of the coating layers but also the breakdown of the coating layers via the conversion mechanism of Reaction 3.

The formation and growth of SiC and SiC/Si₃N₄ coatings on the graphite can be explained by the following steps: i) SiO vapor is generated from the reaction of the mixed Si and SiO₂ powders; ii) SiO vapor diffuses into the gas phase; iii) SiO vapor and carbon of the substrate surface react to form SiC; iv) C and Si diffuse into the SiC layer along the SiC phase boundaries; and v) C and Si react to form and grow SiC on the internal interface. Finally, under N₂ atmosphere, Reaction 3 will occur to form Si₃N₄ on the surface of substrate.

Mechanical Properties of Coating Layers

The specimens selected for hardness measurement were sectioned selectively, ground to a 10 μm finish, and then polished to a 1 μm finish. The top surface was lightly polished, and finished using a 1 μm diamond paste before scratch tests were carried out. Ultra-micro Vickers indentation tests (MZT-511, Mitutoyo, Japan) and scratch tests (UMT, Center for Tribology Inc., USA) were conducted to examine the mechanical properties.

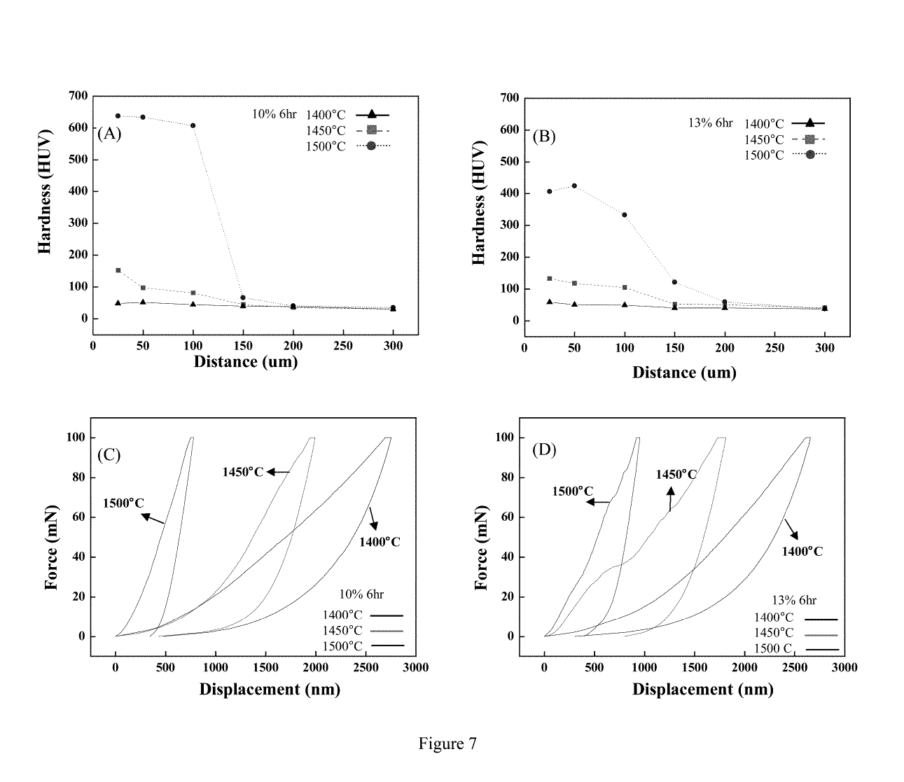

FIG. 7 is graphs depicting the hardness values of SiC coating layers synthesized on graphite substrates with different porosities of (A) 10% and (B) 13% with a dwell time of 6 hours at different temperatures, and displacement versus force curves of coating layers obtained at 50 μm from the surface.

Referring to FIG. 7, it can be seen that the hardness of the synthesized coating layer is proportional to the reaction temperature. The hardness of the coating layer synthesized at 1400° C. was similar to that of the bare graphite. However, the hardness of the coating layer was higher when synthesized at 1500° C., which is about 10˜15 times that of bare graphite. Specifically, the hardness values of the coatings synthesized at 1500° C. with a dwell time of 6 hours were 630 HVU for the graphite of 10% porosity and about 400 HUV of 13% porosity.

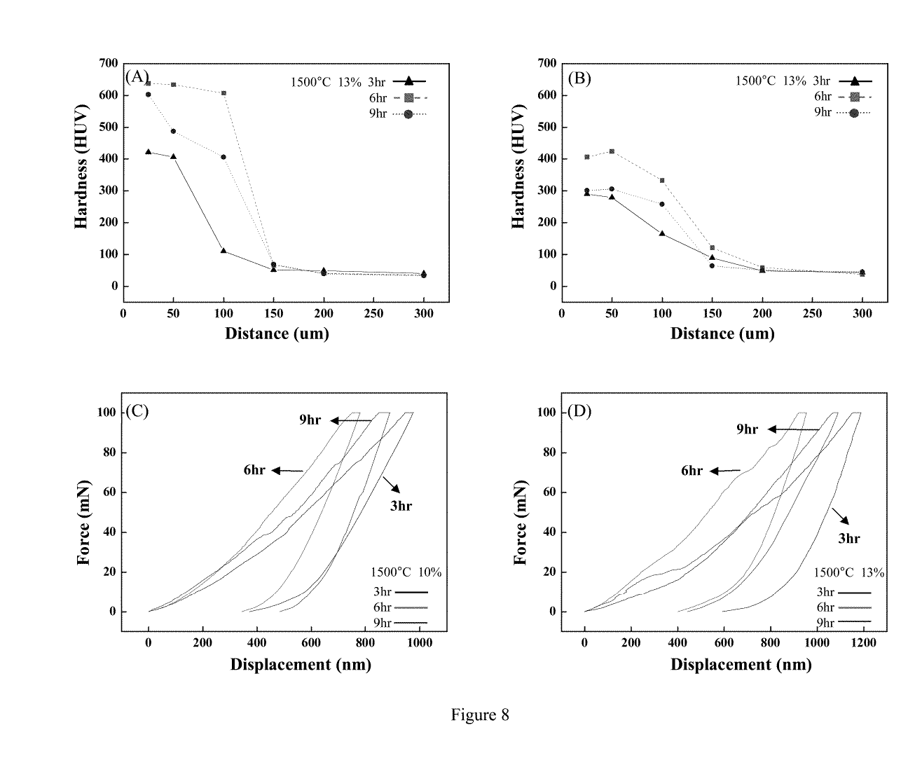

FIG. 8 is graphs depicting the hardness values of SiC coating layers synthesized on the substrates with different porosities of (A) 10% and (B) 13% and with different dwell times at 1500° C., and displacement versus force curves of coating layers obtained at 50 μm from the surface.

Referring to FIG. 8, it can be seen that the hardness of the coating layer formed on the graphite with a porosity of 10% is higher than that formed on the graphite with a porosity of 13%. This is because the substrate with a porosity of 10% is denser and the coating layer formed on the graphite with a porosity of 13% has more pores in the coating and substrate.

The hardness of the coating layer formed on the graphite with 10% porosity changes suddenly, whereas that of the graphite of 13% porosity changes gradually from the surface of the graphite into the graphite. When the dwell time was increased to 9 hours, the hardness of both coating layers decreased.

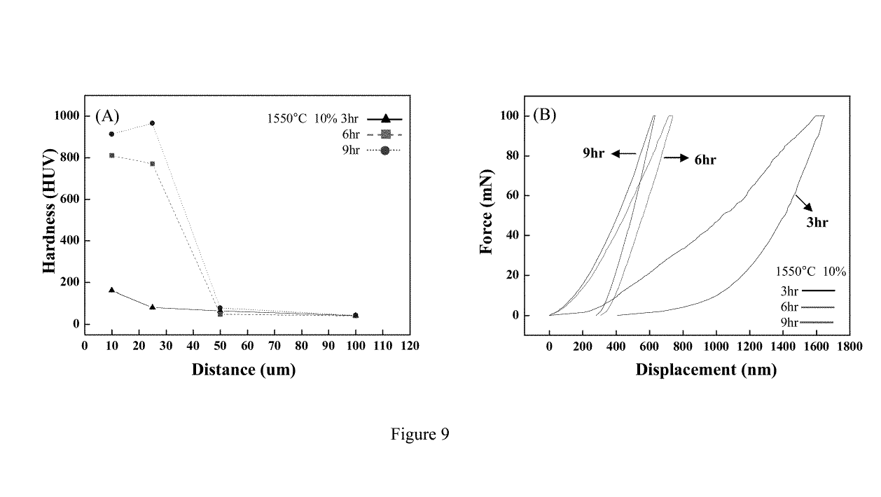

FIG. 9 is graphs depicting the hardness values of SiC/Si₃N₄ coating layers formed on the graphite with a porosity of 10% with different dwell times at 1550° C. under N₂ atmosphere, and displacement versus force curves of the coating layers obtained at 25 μm from the surface. The hardness of the coating layer is obviously affected by the dwell time. Specifically, the hardness increases quickly from 200 to 800 HUV when the dwell time is increased from 3 to 6 hours. However, there is little increase in hardness when the dwell time is increased from 6 to 9 hours, showing about 930 HUV at 9 hours.

Under N₂ atmosphere, the loose coating layer formed initially is concentrated into a relatively dense layer as the dwell time is increased. Compared with the hardness of coating layer is formed on the graphite with 13% porosity under Ar/H₂ atmosphere, the hardness of the coating layer synthesized on the graphite with 10% porosity under N₂ atmosphere is about two times higher than that synthesized under Ar/H₂ atmosphere, even though the thickness of the coating layer is much thinner than that formed under Ar/H₂ atmosphere.

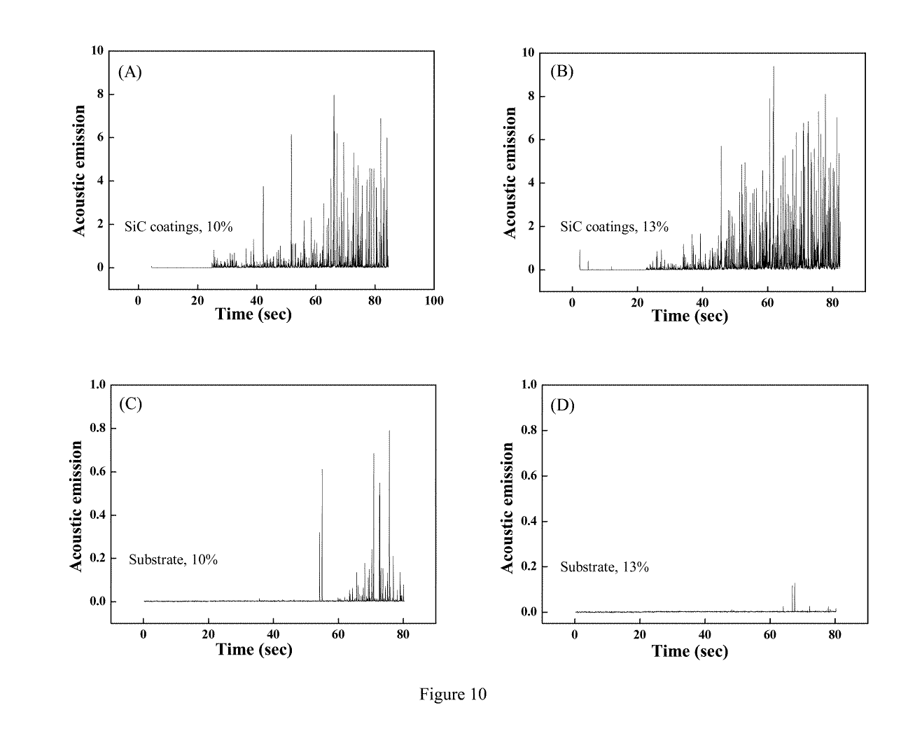

FIG. 10 is graphs for comparing acoustic emission counts during scratch tests on SiC coatings formed on graphite substrates and on bare graphite substrates. The SiC coatings were synthesized on graphite substrates with different porosities of (A) 10% and (B) 13% at 1500° C. with a dwell time of 6 hours. Bare graphite substrates had different porosities of (C) 10% and (D) 13%.

Referring to FIG. 10, it can be seen that acoustic emission signals increase with increase of scratching time, which corresponds to increase of applied load. A more pronounced number of acoustic emission signals appeared in the graphite with 13% porosity than 10% porosity, whereas the critical load of the coating layer was about 22 N in both cases.

Both coating layers had the same friction coefficient of about 0.7 in spite of different porosities of the substrates. This clearly indicates that the wear resistance of the graphite substrate is improved by the coating layer, and the porosity of the graphite substrate does not affect the critical load of the coating layer, whereas the critical load and the friction coefficient of the graphite substrate without a coating layer are strongly affected by the porosity.

Oxidation Resistance of SiC and SiC/Si₃N₄ Coated Graphite Substrates

Thermal oxidation tests were performed at 800° C. or more for three samples of bare graphite, SiC coated graphite, and SiC/Si₃N₄ coated graphite.

A crucible was heated to a predetermined temperature and then the sample was placed in the crucible. Inside the crucible, one side of the sample was exposed to high temperature and the other side was air-cooled to simulate a real application environment. After the oxidation test, the sample was removed and cooled to room temperature. The sample was weighed using a balance with a sensitivity of 0.01 mg.

The surface of the coating layers was observed before and after the oxidation tests with the SEM. Cross-sectional microstructures were also observed.

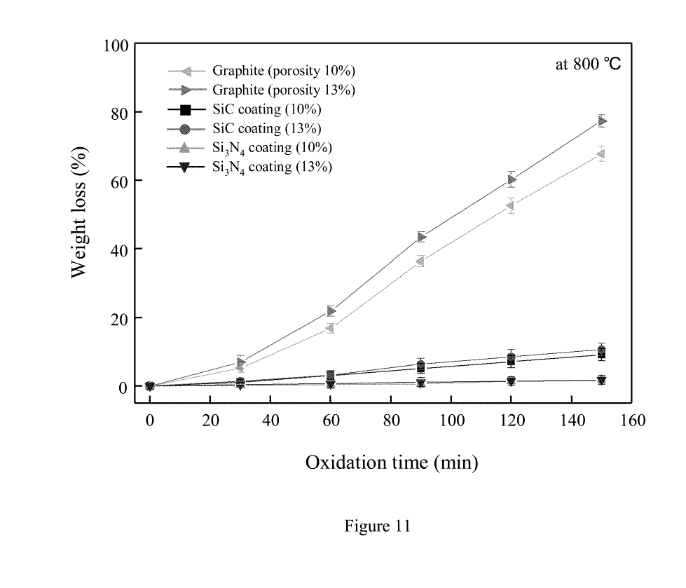

FIG. 11 is graphs for comparing the results of heat treatment tests performed on bare graphite substrates, SiC coated graphite substrates, and SiC/Si₃N₄ coated graphite substrates at 800° C.

As can be seen from FIG. 11, the weight loss of bare graphite reached 80% when it was exposed to 800° C. for up to 150 minutes. The weight loss decreased significantly in SiC coated graphite substrate (10%) and there was no weight loss in Si₃N₄ coated graphite substrate.

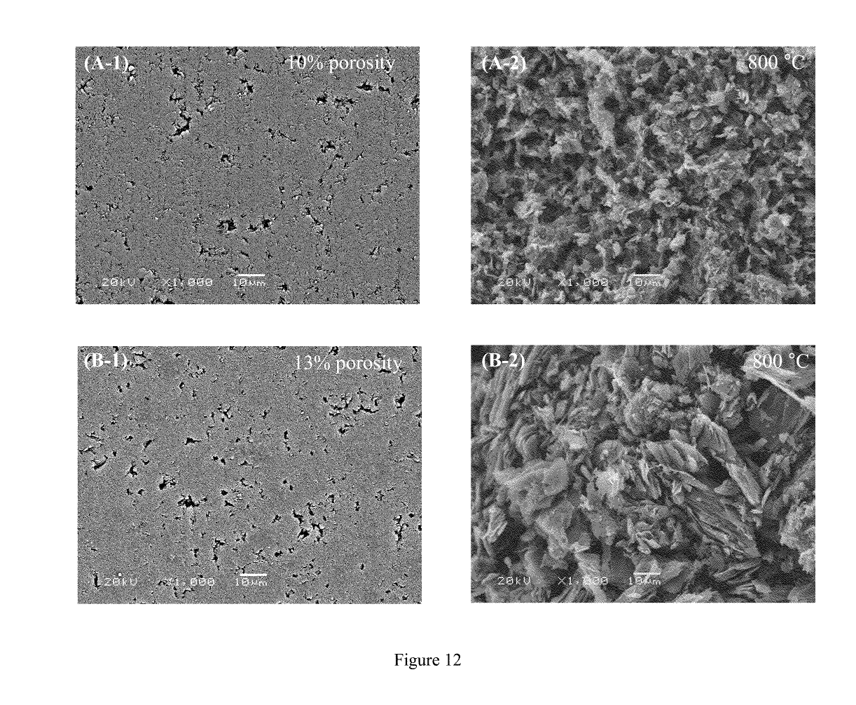

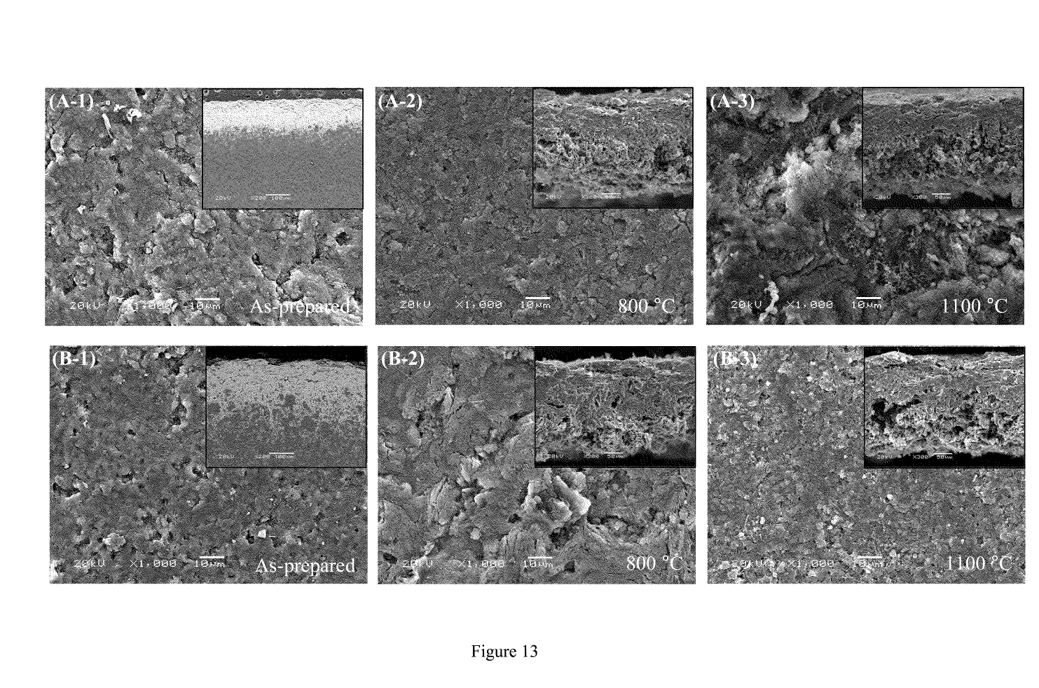

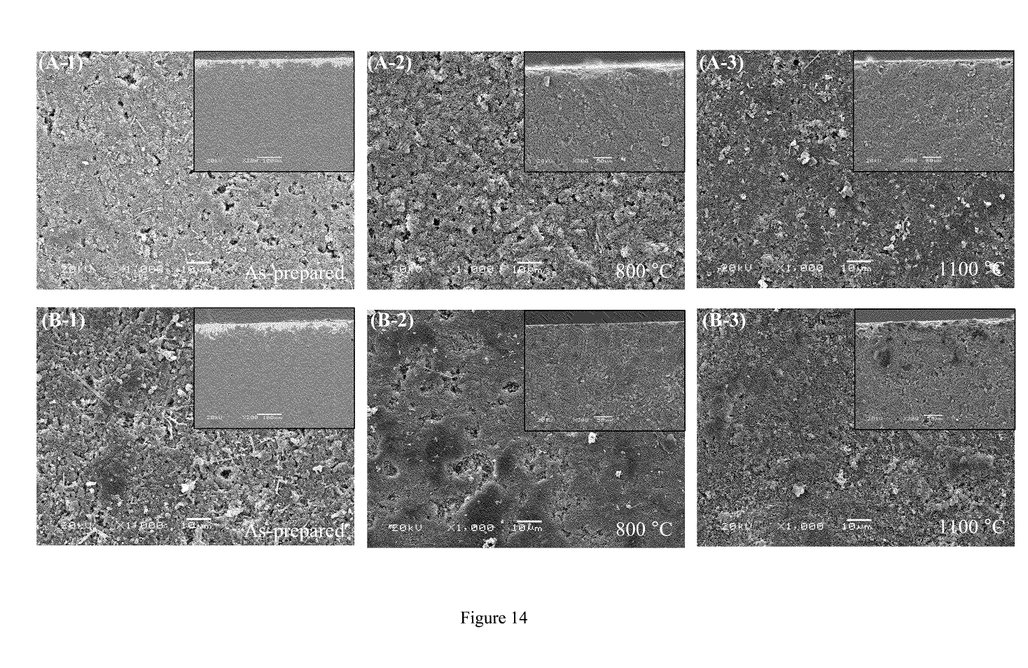

FIGS. 12 to 14 are surface micrographs of bare graphite substrates and coated graphite substrates with porosities of (A) 10% porosity and (B) 13% before and after thermal oxidation tests. Specifically, FIG. 12 is surface micrographs of bare graphite substrates before and after thermal oxidation tests at 800° C. for 150 minutes. FIG. 13 is surface and cross-sectional micrographs of SiC coated graphite substrates (A-1 and B-1) before oxidation tests, (A-2 and B-2) after oxidation tests at 800° C. for 150 minutes, and (A-3 and B-3) after oxidation tests at 1100° C. for 150 minutes. In addition, FIG. 14 is surface and cross-sectional micrographs of SiC/Si₃N₄ coated graphite substrates (A-1 and B-1) before oxidation tests, (A-2 and B-2) after oxidation tests at 800° C. for 150 minutes, and (A-3 and B-3) after oxidation tests at 1100° C. for 150 minutes.

Referring to FIG. 12, which shows thermal oxidation test results for bare graphite, there was a significant change in surface morphologies before and after the tests. It is believed that such a significant change in surface morphologies is caused by expansion of the pores present on the surface and inside the substrate via thermal oxidation. It is consistent with the observation that the expansion of pores is more prominent in bare graphite sample with 13% porosity than 10% porosity.

Referring to FIGS. 13 and 14, expansion of pores was observed on the surface of SiC or SiC/Si₃N₄ coated graphite substrates after thermal oxidation at 800° C. However, change in surface morphologies was not so prominent as in bare graphite (FIG. 12). Interestingly, pores disappeared from the surface of the SiC or SiC/Si₃N₄ coated graphite substrates when the thermal oxidation temperature was increased from 800° C. to 1100° C., differently from the bare graphite samples.

The thickness of the SiC coating layer was much thicker than that of the SiC/Si₃N₄ coating layer, but the SiC/Si₃N₄ coated sample exhibited better resistance to thermal oxidation in the thermal oxidation tests. This result was consistent in both graphite substrates of 10% and 13% porosities.

### INDUSTRIAL APPLICABILITY

The present invention provides a method of modifying a graphite substrate comprising forming a ceramic coating layer, and is applicable to the production of carbon materials.

1. A method of modifying a graphite substrate, comprising:
adding silicon (Si) powder and silicon dioxide (SiO₂) powder into a high-temperature reaction chamber holding a bare graphite substrate; and
heating the high-temperature reaction chamber at a temperature of 1400˜1600° C. for 3 to 9 hours while supplying an inert gas and hydrogen to form a 50 μm to 1000 μm thick SiC coating layer on the surface of the graphite substrate.

2. A method of modifying a graphite substrate comprising:
adding silicon (Si) powder and silicon dioxide (SiO₂) powder to a high-temperature reaction chamber holding a bare graphite substrate; and
heating the high-temperature reaction chamber at a temperature of 1450˜1650° C. for 3 to 9 hours while supplying N₂ gas to form a 30 μm to 600 μm thick SiC/Si₃N₄ coating layer on the surface of the graphite substrate.

3. The method according to claim 1, wherein the bare graphite substrate has a porosity in the range of 5˜20%.

4. A graphite substrate modified by the method according to claim 1.
